(19) United States
(12) Patent Application Publication
(10) Pub. No.: US 2026/0191032 A1
(43) Pub. Date: Jul. 2, 2026

(54) METHOD FOR PRODUCING SEMICONDUCTOR DEVICE, AND SEMICONDUCTOR DEVICE

(71) Applicant: ROHM CO., LTD., Kyoto-shi (JP)

(72) Inventor: Tsunehisa ONO, Kyoto-shi (JP)

(21) Appl. No.: 19/544,715

(22) Filed: Feb. 19, 2026

Related U.S. Application Data
(63) Continuation of application No. PCT/JP2024/028036, filed on Aug. 6, 2024.

(30) Foreign Application Priority Data
Aug. 29, 2023 (JP) 2023-138670

(51) Int. Cl. H10W 70/40; H10W 70/04; H10W 72/00; H10W 74/01; H10W 74/10; H10W 90/00

(52) U.S. Cl. CPC H10W 70/429; H10W 70/048; H10W 74/01; H10W 74/114; H10W 72/884; H10W 90/736; H10W 90/756

(57) ABSTRACT

A method for manufacturing a semiconductor device includes a first step, a second step third step, and a fourth step. In the third step, a pad portion is exposed from a bottom surface of a sealing resin. In the third step, a dimension of the sealing resin in a first direction extending from the bottom surface to a second surface of a first support portion is made smaller than a dimension of the sealing resin in the first direction extending from a top surface of the sealing resin to a first surface of the first support portion. In the fourth step, the first support portion is cut by applying a compressive force to the top surface while the second surface is supported by a supporting member. In the fourth step, a first end surface, which faces one side in a second direction and is exposed from the sealing resin, is formed in the first support portion.

### TECHNICAL FIELD

The present disclosure relates to a method for manufacturing a semiconductor device and a semiconductor device obtained by the manufacturing method.

### BACKGROUND ART

Resin-packaged semiconductor devices, such as a semiconductor device disclosed in JP-A-2018-60908, are widely known. The semiconductor device disclosed in JP-A-2018-60908 includes a semiconductor element, a first lead electrically connected to the semiconductor element, a second lead on which the semiconductor element is mounted, and a sealing resin covering the semiconductor element. The first lead and the second lead protrude from the sealing resin.

The second lead of the semiconductor device disclosed in JP-A-2018-60908 has a second pad portion on which the semiconductor element is mounted. The second pad portion is provided with a protrusion. The protrusion protrudes in a direction perpendicular to a normal direction of a second-pad surface facing the semiconductor element. In the configuration of the semiconductor device, the protrusion of the second pad portion may be used as a support member that connects the second lead to a lead frame. In the manufacturing of the semiconductor device in this case, it is necessary to separate the protrusion from the lead frame after forming the sealing resin. At this stage, a load is applied to the second lead including the protrusion, which causes greater stress to be concentrated in a portion of the sealing resin that is in contact with the second lead. As a result, a crack may occur in the sealing resin.

### BRIEF DESCRIPTION OF THE DRAWINGS

FIG. 1 is a perspective view showing a semiconductor device according to a first embodiment of the present disclosure.

FIG. 2 is a plan view showing the semiconductor device in FIG. 1.

FIG. 3 is a plan view corresponding to FIG. 2, as seen through a sealing resin.

FIG. 4 is a bottom view showing the semiconductor device in FIG. 1.

FIG. 5 is a bottom view corresponding to FIG. 4, as seen through the sealing resin.

FIG. 6 is a front view showing the semiconductor device in FIG. 1.

FIG. 7 is a right-side view showing the semiconductor device in FIG. 1.

FIG. 8 is a left-side view showing the semiconductor device in FIG. 1.

FIG. 9 is a cross-sectional view along line IX-IX in FIG. 3.

FIG. 10 is a cross-sectional view along line X-X in FIG. 3.

FIG. 11 is a cross-sectional view along line XI-XI in FIG. 3.

FIG. 12 is a partially enlarged view of FIG. 5.

FIG. 13 is a partially enlarged view of FIG. 9.

FIG. 14 is a partially enlarged cross-sectional view showing a semiconductor device according to a variation of the first embodiment of the present disclosure.

FIG. 15 is a cross-sectional view showing a manufacturing step of the semiconductor device in FIG. 1.

FIG. 16 is a cross-sectional view showing a manufacturing step of the semiconductor device in FIG. 1.

FIG. 17 is a cross-sectional view showing a manufacturing step of the semiconductor device in FIG. 1.

FIG. 18 is a cross-sectional view showing a manufacturing step of the semiconductor device in FIG. 1.

FIG. 19 is a cross-sectional view showing a manufacturing step of the semiconductor device in FIG. 14.

FIG. 20 is a cross-sectional view showing a manufacturing step of the semiconductor device in FIG. 14.

FIG. 21 is a plan view showing a semiconductor device according to a second embodiment of the present disclosure, as seen through a sealing resin.

FIG. 22 is a bottom view showing the semiconductor device in FIG. 21, as seen through the sealing resin.

FIG. 23 is a cross-sectional view along line XXIII-XXIII in FIG. 21.

FIG. 24 is a cross-sectional view along line XXIV-XXIV in FIG. 21.

FIG. 25 is a partially enlarged view of FIG. 22.

FIG. 26 is a partially enlarged view of FIG. 23.

FIG. 27 is a partially enlarged cross-sectional view showing a semiconductor device according to a variation of the second embodiment of the present disclosure.

FIG. 28 is a cross-sectional view showing a manufacturing step of the semiconductor device in FIG. 21.

FIG. 29 is a cross-sectional view showing a manufacturing step of the semiconductor device in FIG. 21.

FIG. 30 is a cross-sectional view showing a manufacturing step of the semiconductor device in FIG. 21.

FIG. 31 is a cross-sectional view showing a manufacturing step of the semiconductor device in FIG. 27.

### DETAILED DESCRIPTION OF EMBODIMENTS

Details of the present disclosure will be described with reference to the accompanying drawings.

### First Embodiment

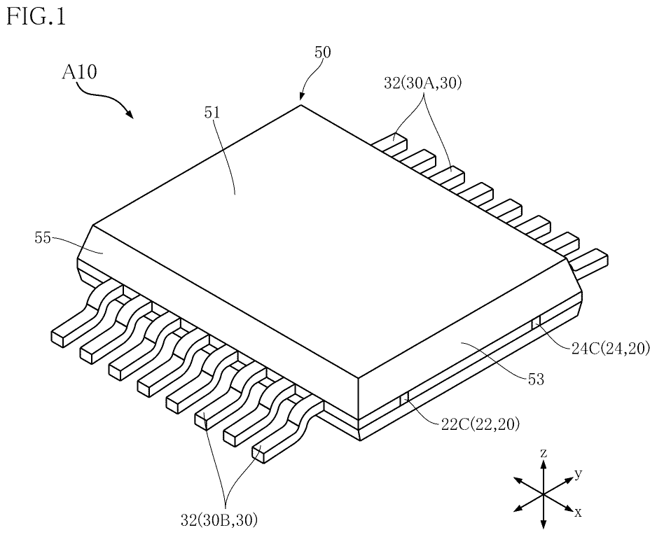

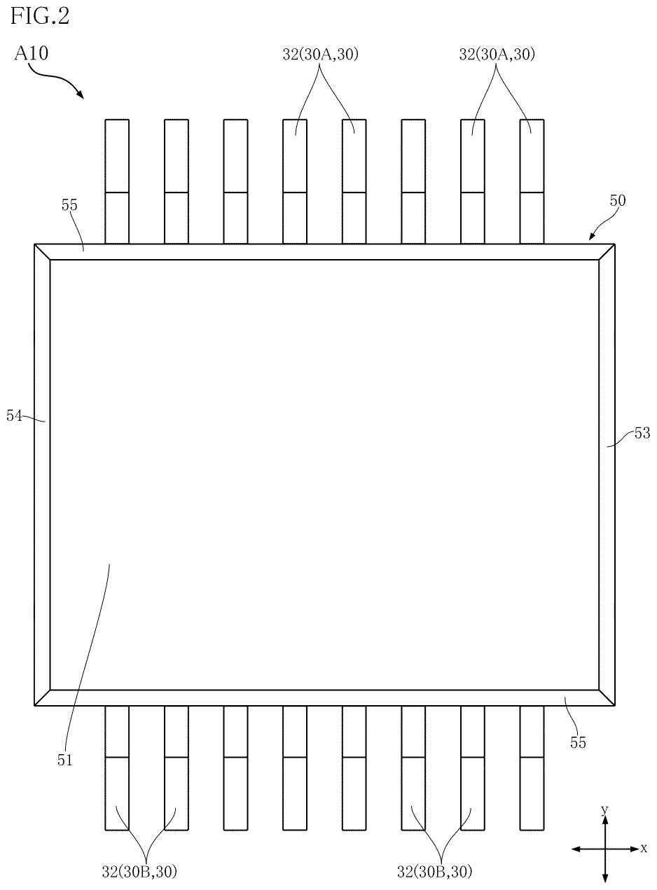

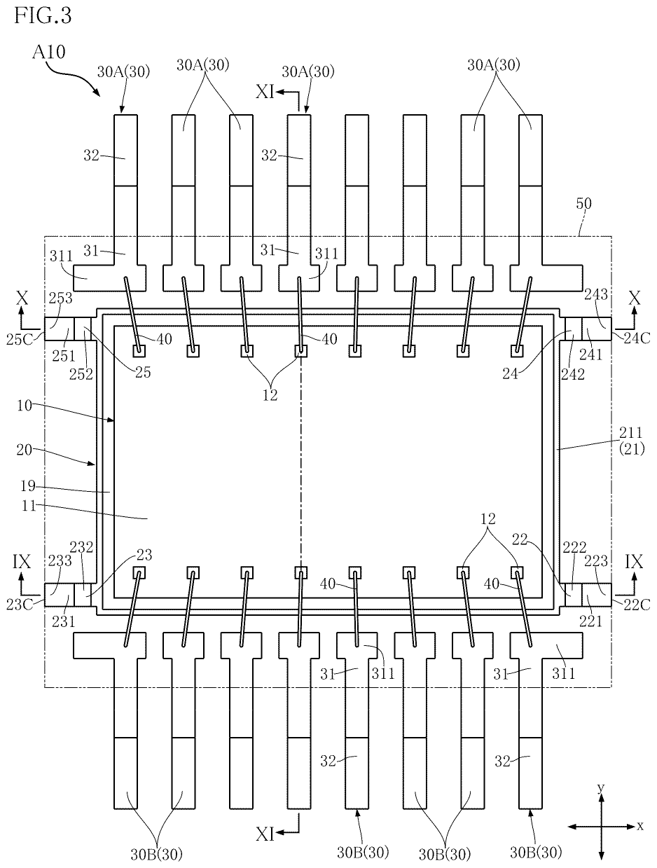

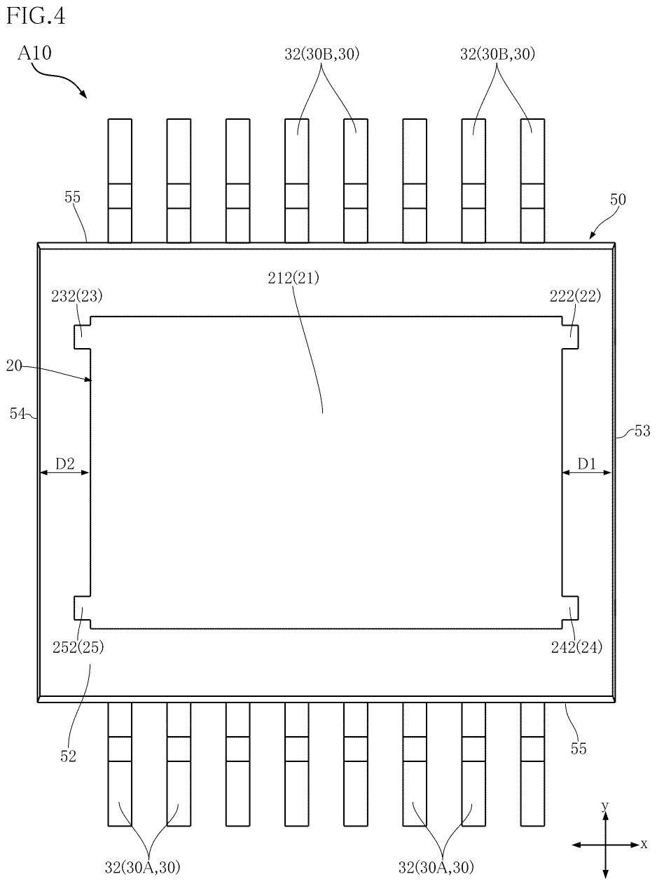

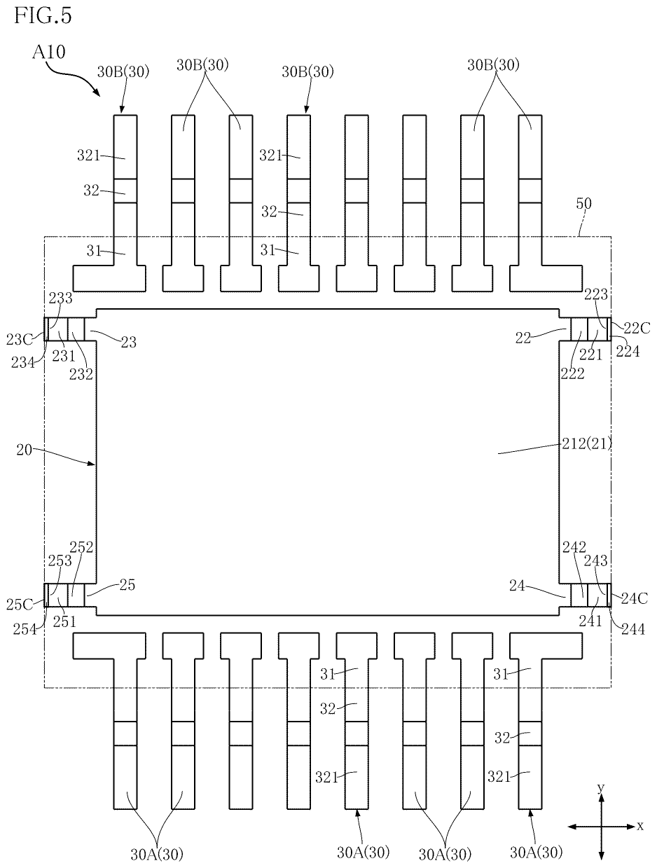

The following describes a semiconductor device A10 according to a first embodiment of the present disclosure, with reference to FIGS. 1 to 13. The semiconductor device A10 includes a semiconductor element 10, a first lead 20, a plurality of second leads 30, a plurality of wires 40, and a sealing resin 50. The semiconductor device A10 is provided in a small outline package (SOP). However, the package type of the semiconductor device A10 is not limited to an SOP. In FIGS. 3 and 5, the sealing resin 50 is shown in phantom for convenience of understanding. In FIGS. 3 and 5, the outline of the sealing resin 50 is indicated by imaginary lines (two-dot chain lines).

In the description of the semiconductor device A10, the normal direction of a mounting surface 211 of a pad portion 21 described below will be referred to as a “first direction z” for convenience. A direction perpendicular to the first direction z will be referred to as a “second direction x”. The direction perpendicular to the first direction z and the second direction x will be referred to as a “third direction y”.

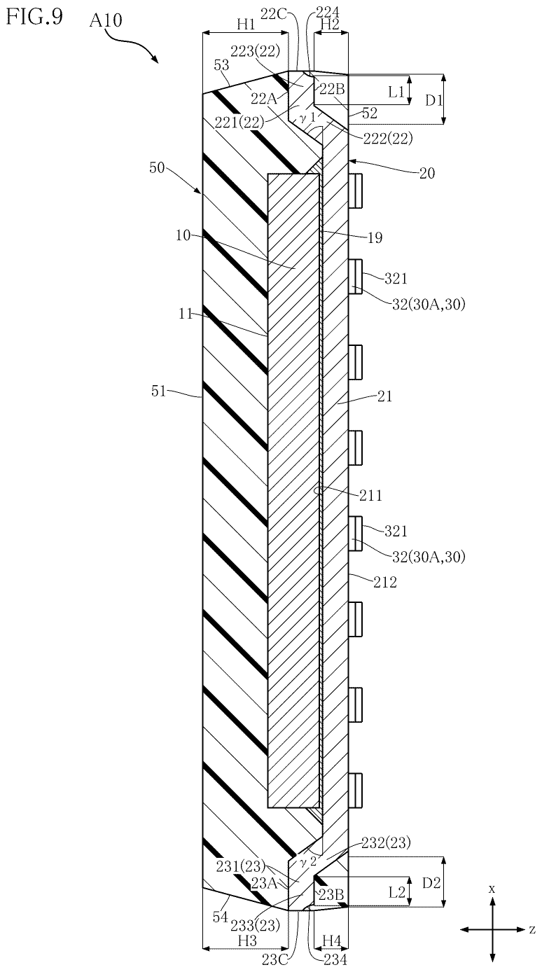

As shown in FIGS. 9 to 11, the sealing resin 50 covers the semiconductor element 10 part of the first lead 20, a part of each of the second leads 30, and the wires 40. The sealing resin 50 is an insulator. The sealing resin 50 is made of a material containing epoxy resin, for example. The sealing resin 50 has a rectangular shape, as viewed in the first direction z.

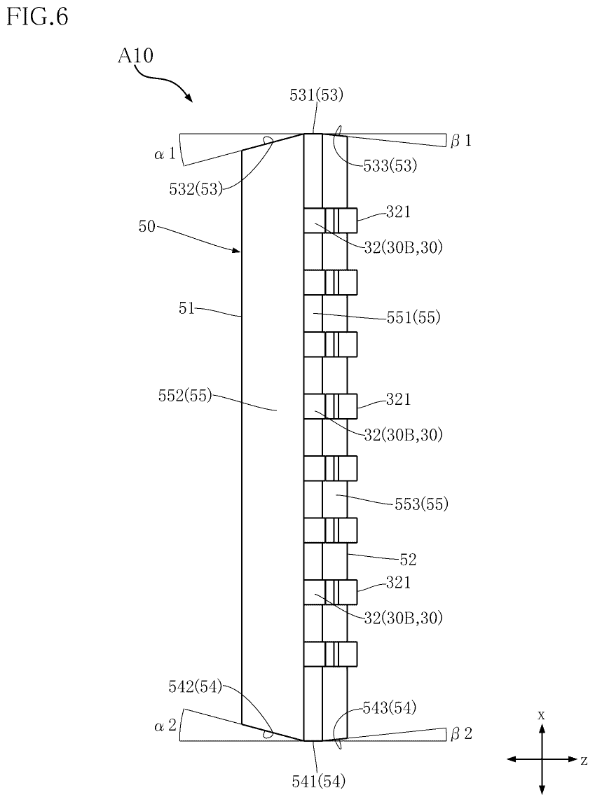

As shown in FIGS. 6 to 8, the sealing resin 50 has a top surface 51, a bottom surface 52, a first side surface 53, a second side surface 54, and two third side surfaces 55.

As shown in FIGS. 6 to 8, the top surface 51 faces one side in the first direction z. The top surface 51 faces the same side as the mounting surface 211 of the pad portion 21 described below in the first direction z. The bottom surface 52 faces away from the top surface 51 in the first direction z.

As shown in FIG. 6, the first side surface 53 is connected to the top surface 51 and bottom surface 52, and faces one side in the second direction x. The first side surface 53 includes a first region 531, a second region 532, and a third region 533. The first region 531 includes the first direction z as an in-plane direction. As viewed in the first direction z, the first region 531 is located outside the top surface 51 and the bottom surface 52. The second region 532 is located between the first region 531 and the top surface 51 in the first direction z. The third region 533 is located opposite the second region 532 with respect to the first region 531. The second region 532 and the third region 533 are inclined relative to the first region 531. The inclination angle α1 of the second region 532 relative to the first region 531 is larger than the inclination angle β1 of the third region 533 relative to the first region 531.

As shown in FIG. 6, the second side surface 54 is connected to the top surface 51 and the bottom surface 52, and faces away from the first side surface 53 in the second direction x. The second side surface 54 includes a fourth region 541, a fifth region 542, and a sixth region 543. The fourth region 541 includes the first direction z as an in-plane direction. As viewed in the first direction z, the fourth region 541 is located outside the top surface 51 and the bottom surface 52. The fifth region 542 is located between the fourth region 541 and the top surface 51 in the first direction z. The sixth region 543 is located opposite the fifth region 542 with respect to the fourth region 541. The fifth region 542 and the sixth region 543 are inclined relative to the fourth region 541. The inclination angle α2 of the fifth region 542 relative to the fourth region 541 is larger than the inclination angle β2 of the sixth region 543 relative to the fourth region 541.

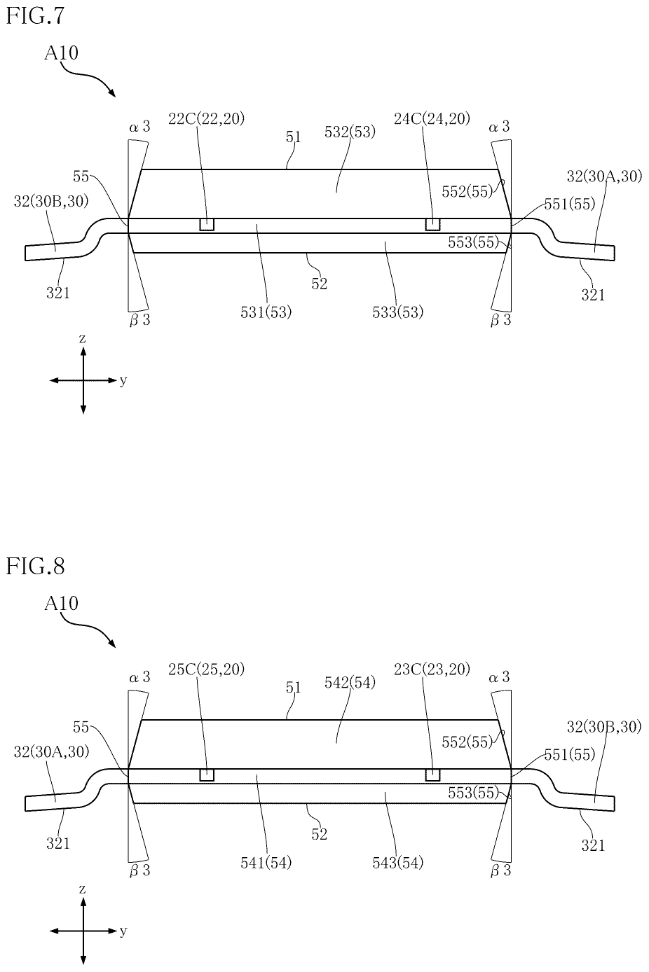

As shown in FIGS. 7 and 8, the two third side surfaces 55 are connected to the top surface 51 and the bottom surface 52, and face away from each other in the third direction y. Each of the two third side surfaces 55 includes a seventh region 551, an eighth region 552, and a ninth region 553. The seventh region 551 includes the first direction z as an in-plane direction. As viewed in the first direction z, the seventh region 551 is located outside the top surface 51 and the bottom surface 52. The eighth region 552 is located between the seventh region 551 and the top surface 51 in the first direction z. The ninth region 553 is located opposite the eighth region 552 with respect to the seventh region 551. The eighth region 552 and the ninth region 553 are inclined relative to the seventh region 551. The inclination angle α3 of the eighth region 552 relative to the seventh region 551 is equal to the inclination angle β3 of the ninth region 553 relative to the seventh region 551.

Each of the first lead 20 and the second leads 30 contains copper (Cu). The first lead 20 and the second leads 30 are obtained from the same lead frame.

As shown in FIGS. 3 and 9 to 11, the semiconductor element 10 is mounted on the first lead 20. The first lead 20 has a pad portion 21, a first support portion 22, a second support portion 23, a third support portion 24, and a fourth support portion 25.

As shown in FIGS. 3 and 9 to 11, the semiconductor element 10 is mounted on the pad portion 21. As viewed in the first direction z, the pad portion 21 has a rectangular shape. The pad portion 21 has a mounting surface 211 and an exposed surface 212. The mounting surface 211 faces one side in the first direction z. The semiconductor element 10 is mounted on the mounting surface 211. The exposed surface 212 faces away from the mounting surface 211 in the first direction z. The exposed surface 212 is exposed from the bottom surface 52 of the sealing resin 50.

As shown in FIGS. 3, 5, and 9, the first support portion 22 is connected to the pad portion 21 on one side in the second direction x. The first support portion 22 is located closer to the first side surface 53 of the sealing resin 50 than to the second side surface 54 of the sealing resin 50. The first support portion 22 has a first surface 22A, a second surface 22B, and a first end surface 22C. The first surface 22A faces the same side as the mounting surface 211 in the first direction z. The second surface 22B faces away from the first surface 22A in the first direction z. The first surface 22A and the second surface 22B are covered with the sealing resin 50. The first end surface 22C faces one side in the second direction x. The first end surface 22C is exposed from the first region 531 of the first side surface 53.

As shown in FIG. 9, the dimension H2 of the sealing resin 50 in the first direction z extending from the bottom surface 52 of the sealing resin 50 to the second surface 22B is smaller than the dimension H1 of the sealing resin 50 in the first direction z extending from the top surface 51 of the sealing resin 50 to the first surface 22A. In this case, it is preferable that the dimension H2 be no greater than 50% of the dimension H1. The dimension L1 of the second surface 22B in the second direction x is no less than 50% of the dimension D1 of an area of the bottom surface 52 in the second direction x, where the area is adjacent to the exposed surface 212 of the pad portion 21 on one side in the second direction x and overlaps with the second surface 22B as viewed in the first direction z.

As shown in FIGS. 3, 5, and 9, the first support portion 22 has a first main portion a first connecting portion 222, and a first end portion 223. The first main portion 221 includes the first surface 22A and the second surface 22B. The first connecting portion 222 is connected to the first main portion 221 and the pad portion 21. The first connecting portion 222 is inclined relative to the mounting surface 211 toward a side away from the pad portion 21 in the second direction x. It is preferable that the inclination angle γ1 of the first connecting portion 222 relative to the mounting surface 211 be no greater than 50°. The first end portion 223 is located opposite the first connecting portion 222 with respect to the first main portion 221 in the second direction x, and is connected to the first main portion 221. The first end portion 223 includes the first surface 22A, the second surface 22B, and the first end surface 22C.

As shown in FIGS. 5 and 9, the first end portion 223 of the first support portion 22 is provided with a first recess 224 recessed from the second surface 22B. The first recess 224 is connected to the first main portion 221 and the first end surface 22C. In the semiconductor device A10, the first recess 224 is provided in the first end portion 223, so that the cross-sectional area of the first end portion 223 taken along a direction perpendicular to the second direction x decreases from the first main portion 221 to the first end surface 22C.

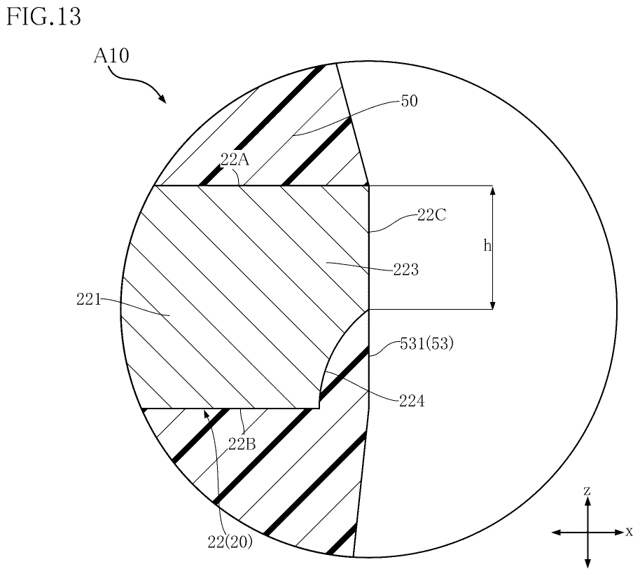

As shown in FIG. 13, the first recess 224 of the first end portion 223 in the first support portion 22 is in contact with the sealing resin 50. The dimension of the first recess 224 in the second direction x is smaller than the dimension L1 of the second surface 22B of the first support portion 22. The first end surface 22C is flush with the first region 531 of the first side surface 53 of the sealing resin 50.

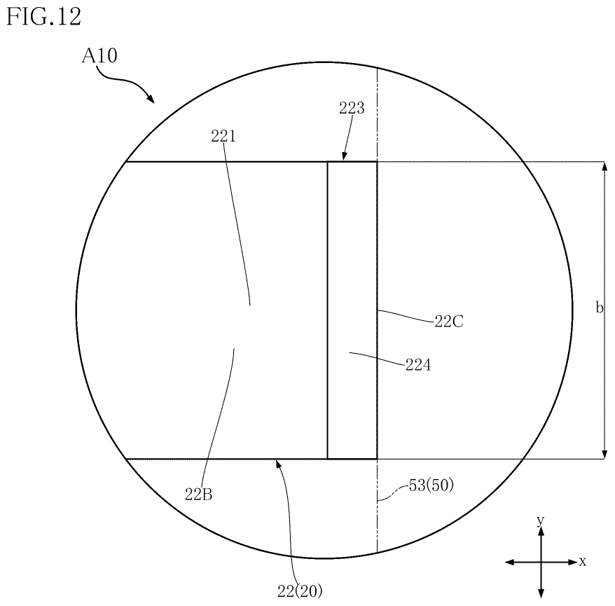

As shown in FIGS. 12 and 13, the dimension b of the first end surface 22C in the direction y is different from the dimension h of the first end surface 22C in the first direction z. In the semiconductor device A10, the dimension h is smaller than the dimension b.

As shown in FIGS. 3, 5, and 9, the second support portion 23 is located opposite the first support portion 22 with respect to the pad portion 21 in the second direction x, and is connected to the pad portion 21. The second support portion 23 is located closer to the second side surface 54 of the sealing resin 50 than to the first side surface 53 of the sealing resin 50. The second support portion 23 has a third surface 23A, a fourth surface 23B, and a second end surface 23C. The third surface 23A faces the same side as the mounting surface 211 in the first direction z. The fourth surface 23B faces away from the third surface 23A in the first direction z. The third surface 23A and the fourth surface 23B are covered with the sealing resin 50. The second end surface 23C faces away from the first end surface 22C of the first support portion 22 in the second direction x. The second end surface 23C is exposed from the fourth region 541 of the second side surface 54.

As shown in FIG. 9, the dimension H4 of the sealing resin 50 in the first direction z extending from the bottom surface 54 of the sealing resin 50 to the fourth surface 23B is smaller than the dimension H3 of the sealing resin 50 in the first direction z extending from the top surface 51 of the sealing resin 50 to the third surface 23A. In this case, it is preferable that the dimension H4 be no greater than 50% of the dimension H3. The dimension L2 of the fourth surface 23B in the second direction x is no less than 50% of the dimension D2 of an area of the bottom surface 52 in the second direction x, where the area is adjacent to the exposed surface 212 of the pad portion 21 on one side in the second direction x and overlaps with the fourth surface 23B as viewed in the first direction z.

As shown in FIGS. 3, 5, and 9, the second support portion 23 has a second main portion 231, a second connecting portion 232, and a second end portion 233. The second main portion 231 includes the third surface 23A and the fourth surface 23B. The second connecting portion 232 is connected to the second main portion 231 and the pad portion 21. The second connecting portion 232 is inclined relative to the mounting surface 211 toward a side away from the pad portion 21 in the second direction x. It is preferable that the inclination angle γ2 of the second connecting portion 232 relative to the mounting surface 211 be no greater than 50°. The second end portion 233 is located opposite the second connecting portion 232 with respect to the second main portion 231 in the second direction x, and is connected to the second main portion 231. The second end portion 233 includes the third surface 23A, the fourth surface 23B, and the second end surface 23C.

As shown in FIGS. 5 and 9, the second end portion 233 of the second support portion 23 provided with a second recess 234 recessed from the fourth surface 23B. The second recess 234 is connected to the second main portion 231 and the second end surface 23C. In the semiconductor device A10, the second recess 234 is provided in the second end portion 233, so that the cross-sectional area of the second end portion 233 taken along a direction perpendicular to the second direction x decreases from the second main portion 231 to the second end surface 23C.

The dimension of the pad portion 21 in the second direction x is at least ten times dimension of each of the first support portion 22 and the second support portion 23 in the second direction x.

As shown in FIGS. 3, 5, and 10, the third support portion 24 is located on the same side as the first support portion 22 with respect to the pad portion 21 in the second direction x, and is connected to the pad portion 21. The third support portion 24 is spaced apart from the first support portion 22 in the third direction y. The third support portion 24 has a fifth surface 24A, a sixth surface 24B, and a third end surface 24C. The fifth surface 24A faces the same side as the mounting surface 211 in the first direction z. The sixth surface 24B faces away from the fifth surface 24A in the first direction z. The fifth surface 24A and the sixth surface 24B are covered with the sealing resin 50. The third end surface 24C faces the same side as the first end surface 22C of the first support portion 22 in the second direction x. The third end surface 24C is exposed from the first region 531 of the first side surface 53 of the sealing resin 50.

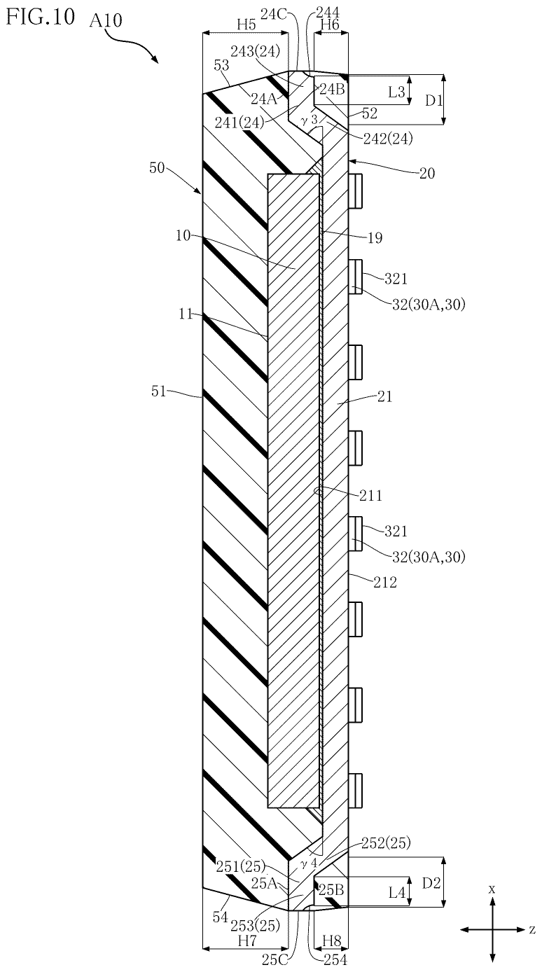

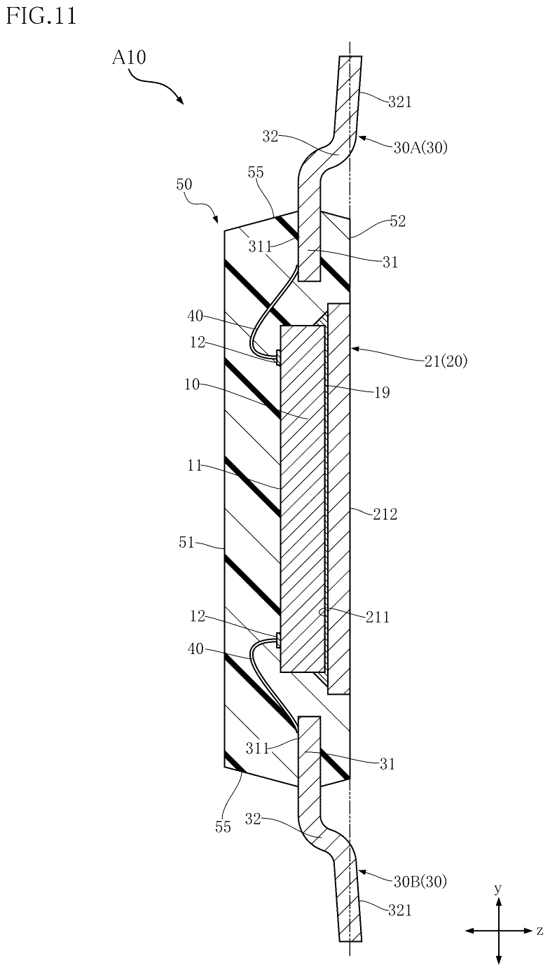

As shown in FIG. 10, the dimension H6 of the sealing resin 50 in the first direction z extending from the bottom surface 52 of the sealing resin 50 to the sixth surface 24B is smaller than the dimension H5 of the sealing resin 50 in the first direction z extending from the top surface 51 of the sealing resin 50 to the fifth surface 24A. In this case, it is preferable that the dimension H6 be no greater than 50% of the dimension H5. The dimension L3 of the sixth surface 24B in the second direction x is no less than 50% of the dimension D1 of an area of the bottom surface 52 in the second direction x, where the area is adjacent to the exposed surface 212 of the pad portion 21 on one side in the second direction x and overlaps with the sixth surface 24B as viewed in the first direction z.

As shown in FIGS. 3, 5, and 10, the third support portion 24 has a third main portion 24 third connecting portion 242, and a third end portion 243. The third main portion 241 includes the fifth surface 24A and the sixth surface 24B. The third connecting portion 242 is connected to the third main portion 241 and the pad portion 21. The third connecting portion 242 is inclined relative to the mounting surface 211 toward a side away from the pad portion 21 in the second direction x. It is preferable that the inclination angle γ3 of the third connecting portion 242 relative to the mounting surface 211 be no greater than 50°. The third end portion 243 is located opposite the third connecting portion 242 with respect to the third main portion 241 in the second direction x, and is connected to the third main portion 241. The third end portion 243 includes the fifth surface 24A, the sixth surface 24B, and the third end surface 24C.

As shown in FIGS. 5 and 10, the third end portion 243 of the third support portion 24 is provided with a third recess 244 recessed from the sixth surface 24B. The third recess 244 is connected to the third main portion 241 and the third end surface 24C. In the semiconductor device A10, the third recess 244 is provided in the third end portion 243, so that the cross-sectional area of the third end portion 243 taken along a direction perpendicular to the second direction x decreases from the third main portion 241 to the third end surface 24C. As shown in FIGS. 3, 5, and 10, the fourth support portion 25 is located on the same side as the second support portion 23 with respect to the pad portion 21 in the second direction x, and is connected to the pad portion 21. The fourth support portion 25 is spaced apart from the second support portion 23 in the third direction y. The fourth support portion 25 has a seventh surface 25A, an eighth surface 25B, and a fourth end surface 25C. The seventh surface 25A faces the same side as the mounting surface 211 in the first direction z. The eighth surface 25B faces away from the seventh surface 25A in the first direction z. The seventh surface 25A and the eighth surface 25B are covered with the sealing resin 50. The fourth end surface 25C faces the same side as the second end surface 23C of the second support portion 23 in the second direction x. The fourth end surface 25C is exposed from the fourth region 541 of the second side surface 54 of the sealing resin 50.

As shown in FIG. 10, the dimension H8 of the sealing resin 50 in the first direction z extending from the bottom surface 52 of the sealing resin 50 to the eighth surface 25B is smaller than the dimension H7 of the sealing resin 50 in the first direction z extending from the top surface 51 of the sealing resin 50 to the seventh surface 25A. In this case, it is preferable that the dimension H8 be no greater than 50% of the dimension H7. The dimension L4 of the eighth surface 25B in the second direction x is no less than 50% of the dimension D2 of an area of the bottom surface 52 in the second direction x, where the area is adjacent to the exposed surface 212 of the pad portion 21 on one side in the second direction x and overlaps with the eighth surface 25B as viewed in the first direction z.

As shown in FIGS. 3, 5, and 10, the fourth support portion 25 has a fourth main portion 251, a fourth connecting portion 252, and a fourth end portion 253. The fourth main portion 251 includes the seventh surface 25A and the eighth surface 25B. The fourth connecting portion 252 is connected to the fourth main portion 251 and the pad portion 21. The fourth connecting portion 252 is inclined relative to the mounting surface 211 toward a side away from the pad portion 21 in the second direction x. It is preferable that the inclination angle γ4 of the fourth connecting portion 252 relative to the mounting surface 211 be no greater than 50°. The fourth end portion 253 is located opposite the fourth connecting portion 252 with respect to the fourth main portion 251 in the second direction x, and is connected to the fourth main portion 251. The fourth end portion 253 includes the seventh surface 25A, the eighth surface 25B, and the fourth end surface 25C.

As shown in FIGS. 5 and 10, the fourth end portion 253 of the fourth support portion 25 provided with a fourth recess 254 recessed from the eighth surface 25B. The fourth recess 254 is connected to the fourth main portion 251 and the fourth end surface 25C. In the semiconductor device A10, the fourth recess 254 is provided in the fourth end portion 253, so that the cross-sectional area of the fourth end portion 253 taken along a direction perpendicular to the second direction x decreases from the fourth main portion 251 to the fourth end surface 25C.

As shown in FIGS. 3 and 9 to 11, the semiconductor element 10 is mounted on the pad portion 21 of the first lead 20. The semiconductor element 10 performs the functions of the semiconductor device A10. The type of the semiconductor element 10 is not particularly limited and may be an IC or an LSI, for example. The semiconductor element 10 is bonded to the mounting surface 211 of the pad portion 21 via a bonding layer 19. The bonding layer 19 is made of a paste containing metal particles. The metal particles are silver (Ag), for example. Thus, the bonding layer 19 is a conductor. Alternatively, the bonding layer 19 may be solder.

As shown in FIGS. 3 and 11, the semiconductor element 10 has an element surface and a plurality of electrodes 12. The element surface 11 faces the same side as the mounting surface 211 of the pad portion 21 in the first direction z. The element surface 11 is located between the top surface 51 of the sealing resin 50 and each of the first surface 22A of the first support portion 22, the third surface 23A of the second support portion 23, the fifth surface 24A of the third support portion 24, and the seventh surface 25A of the fourth support portion 25 in the first direction z. Thus, as viewed in a direction perpendicular to the first direction z, the semiconductor element 10 includes a portion protruding in the first direction z from each of the first support portion 22, the second support portion 23, the third support portion 24, and the fourth support portion 25. The electrodes 12 are provided on the element surface 11. Each of the electrodes 12 is electrically connected to a circuit configured within the semiconductor element 10.

As shown in FIGS. 3 and 5, the second leads 30 are arranged on both sides of the lead 20 in the third direction y. The second leads 30 are electrically connected to the semiconductor element 10. The second leads 30 include a plurality of first terminals 30A and a plurality of second terminals 30B. The first terminals 30A are located on one side of the first lead 20 in the third direction y. The first terminals 30A are aligned along the second direction x. The first terminals 30A protrude from the seventh region 551 of one of the two third side surfaces 55 of the sealing resin 50. The second terminals 30B are located opposite the first terminals 30A with respect to the first lead 20 in the third direction y. The second terminals 30B are aligned along the second direction x. The second terminals 30B protrude from the seventh region 551 of the other one of the two third side surfaces 55.

As shown in FIGS. 3 and 5, each of the second leads 30 has an inner portion 31 an an outer portion 32. The inner portion 31 is covered with the sealing resin 50. As shown in FIGS. 3 and 11, the inner portion 31 of each of the second leads 30 has a connecting surface 311. The connecting surface 311 faces the same side as the mounting surface 211 of the pad portion 21 in the first direction z. The connecting surface 311 is located between the mounting surface 211 and the top surface 51 of the sealing resin 50 in the first direction z. In the semiconductor device A10, the connecting surface 311 is located between the mounting surface 211 and the element surface 11 of the semiconductor element 10 in the first direction z. Furthermore, in the semiconductor device A10, the connecting surface 311 of each of the second leads 30, the first surface 22A of the first support portion 22, the third surface 23A of the second support portion 23, the fifth surface 24A of the third support portion 24, and the seventh surface 25A of the fourth support portion 25 are all within the same plane.

As shown in FIGS. 3 and 5, each of the outer portions 32 is connected to the inner portion 31 of a corresponding one of the second leads 30. The outer portion 32 protrudes from the seventh region 551 of one of the two third side surfaces 55 of the sealing resin 50. The surface of the outer portion 32 is plated with tin, for example. As viewed in the first direction z, the outer portion 32 extends in the third direction y. As viewed in the second direction x, the outer portion 32 is bent into a gull-wing shape.

As shown in FIGS. 5 and 11, the outer portion 32 of each of the second leads 30 has mounting surface 321. The mounting surface 321 is exposed from the sealing resin 50. In the first direction z, the mounting surface 321 faces away from the connecting surface 311 of the corresponding inner portion 31, and is located farthest from the connecting surface 311 of the corresponding inner portion 31. The mounting surface 321 protrudes from the plane containing the bottom surface 52 of the sealing resin 50. The mounting surface 321 is inclined relative to the bottom surface 52.

As shown in FIGS. 3 and 11, each of the wires 40 is electrically bonded to one of the electrodes 12 of the semiconductor element 10 and the connecting surface 311 of one of the second leads 30. Thus, the second leads 30 are electrically connected to the semiconductor element 10. The wires 40 contain gold (Au), for example. Alternatively, the wires 40 may contain aluminum (Al) or copper.

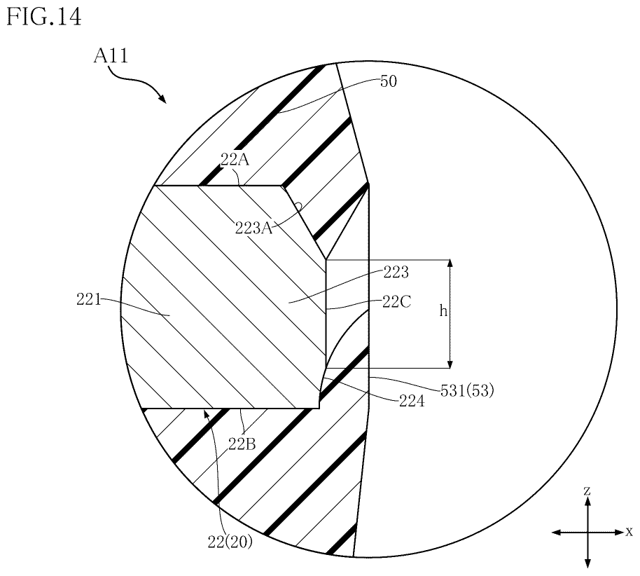

Next, a semiconductor device A11 according to a variation of the first embodiment of the present disclosure will be described with reference to FIG. 14. FIG. 14 corresponds to FIG. 13 that shows the semiconductor device A10. The semiconductor device A11 is different from the semiconductor device A10 in the configuration of the first support portion 22 of the first lead 20.

As shown in FIG. 14, the first end portion 223 has a first intermediate surface 223A, which is located between the first surface 22A and the first end surface 22C in the second direction x and connected to the first surface 22A. As viewed in the second direction x the first intermediate surface 223A overlaps with the first main portion 221. The first end surface 22C is located between the first intermediate surface 223A and the first recess 224 in the first direction z. The dimension of the first intermediate surface 223A in the second direction x is larger than the dimension of the first recess 224 in the second direction x. The first intermediate surface 223A is inclined relative to the first surface 22A toward the inside of the first end portion 223 in the first direction z, and is connected to the first end surface 22C. The first intermediate surface 223A is covered with the sealing resin 50.

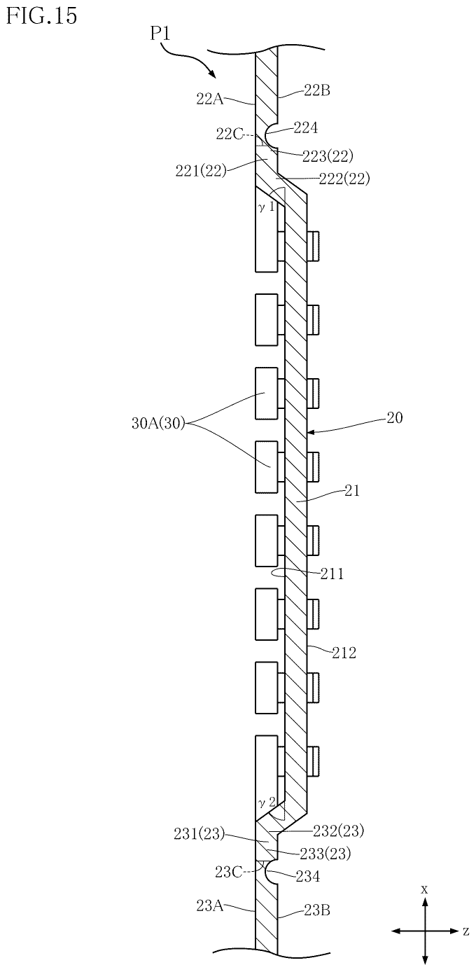

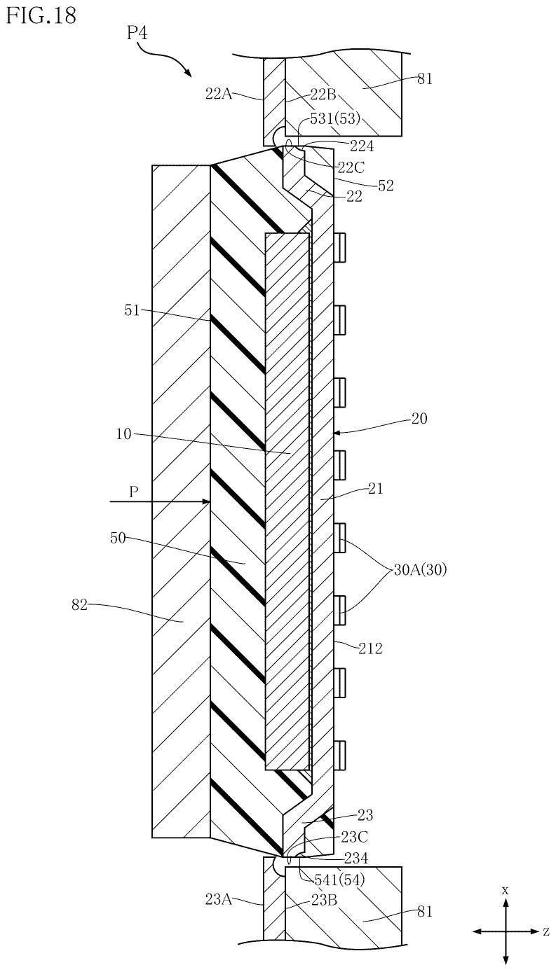

Next, an example of a method for manufacturing the semiconductor device A10 will be described with reference to FIGS. 15 and 18. FIGS. 15 to 18 correspond to FIG. 9 which shows the semiconductor device A10.

First, as shown in FIG. 15, a first step P1 is performed to form a first lead 20 having a pad portion 21, a first support portion 22, and a second support portion 23. The first step P1 is performed during formation of a lead frame including the first lead 20 and a plurality of second leads 30. In the description of the method for manufacturing the semiconductor device A10, the description of forming the third support portion 24 and the fourth support portion 25 of the first lead 20 will be omitted. In the first step P1, a first recess 224 is formed in the first end portion 223 of the first support portion 22, so that the cross-sectional area of the first end portion 223 taken along a direction perpendicular to the second direction x decreases from the first main portion 221 to the first end surface 22C. In addition, a second recess 234 is formed in the second end portion 233 of the second support portion 23, so that the cross-sectional area of the second end portion 233 taken along a direction perpendicular to the second direction x decreases from the second main portion 231 of the second support portion 23 to the second end surface 23C.

Furthermore, as shown in FIG. 15, in the first step P1, the first connecting portion 222 of the first support portion 22 is inclined relative to the mounting surface 211 toward a side away from the pad portion 21 in the second direction x. In addition, the second connecting portion 232 of the second support portion 23 is inclined relative to the mounting surface 211 toward a side away from the pad portion 21 in the second direction x. Each of the inclination angles γ1 and γ2 of the first connecting portion 222 and the second connecting portion 232 relative to the mounting surface 211 is preferably no greater than 50°.

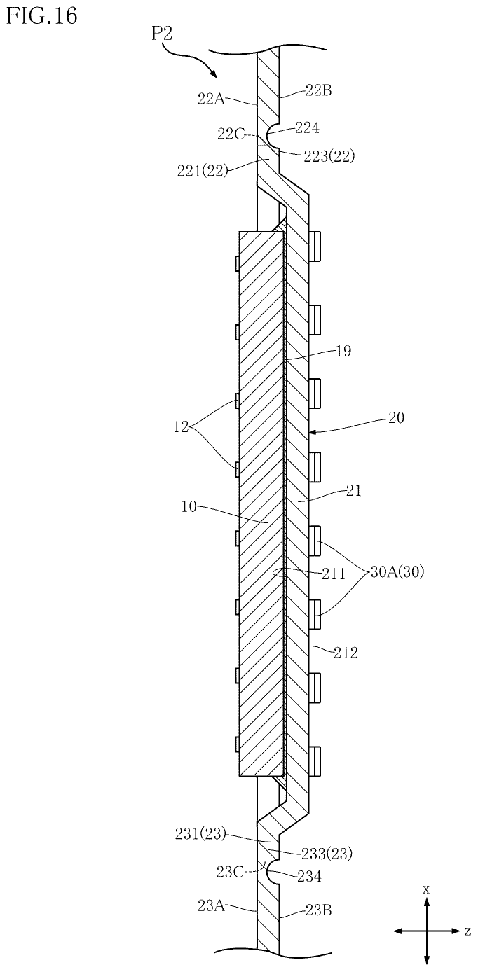

Next, as shown in FIG. 16, a second step P2 is performed to bond a semiconductor element 10 to the mounting surface 211 of the pad portion 21. In the second step P2, the semiconductor element 10 is bonded to the mounting surface 211 via a bonding layer 19. Subsequently, although not illustrated, a plurality of wires 40 are formed by wire bonding, such that the wires 40 are individually conductively bonded to the plurality of electrodes 12 of the semiconductor element 10 and the connecting surfaces 311 of the second leads 30.

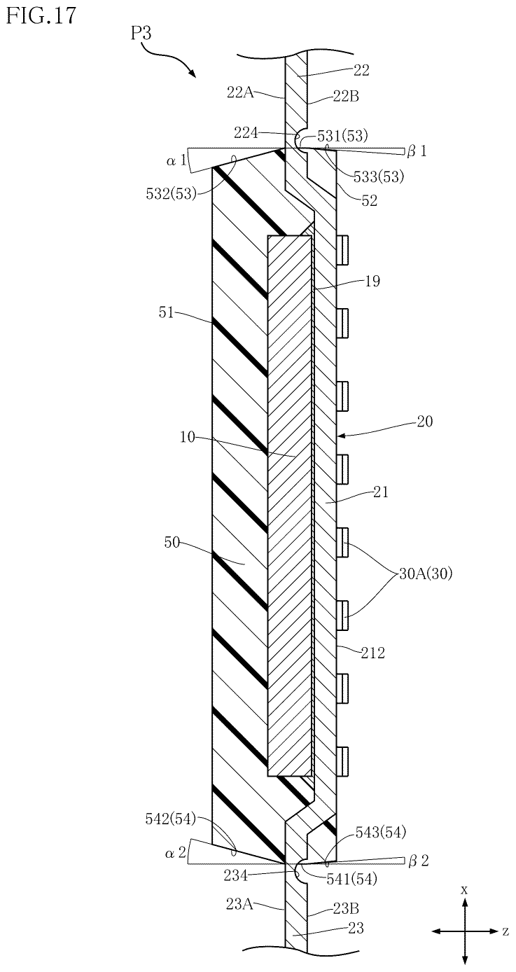

Next, as shown in FIG. 17, a third step P3 is performed to form a sealing resin 50 that covers a part of each of the pad portion 21, the first support portion 22, and the second support portion 23, and the semiconductor element 10. The sealing resin 50 is formed by transfer molding. In the third step P3, a part of each of the first surface 22A and the second surface 22B of the first support portion 22, and a part of each of the third surface 23A and the fourth surface 23B of the second support portion 23 are covered with the sealing resin 50. In this case, at least a part of the first recess 224 formed in the first support portion 22 and at least a part of the second recess 234 formed in the second support portion 23 are covered with the sealing resin 50. In addition, the exposed surface 212 of the pad portion 21 is exposed from the bottom surface 52. Furthermore, the dimension H2 shown in FIG. 9 is made smaller than the dimension H1. In addition, the dimension H4 shown in FIG. 9 is made smaller than the dimension H3.

As shown in FIG. 17, in the third step P3, the first support portion 22 is caused to protrude from the first region 531 of the first side surface 53 of the sealing resin 50. At this time, the inclination angle α1 of the second region 532 of the first side surface 53 relative to the first region 531 is made larger than the inclination angle β1 of the third region 533 of the first side surface 53 relative to the first region 531. In addition, the second support portion 23 is caused to protrude from the fourth region 541 of the second side surface 54 of the sealing resin 50. At this time, the inclination angle α2 of the fifth region 542 of the second side surface 54 relative to the fourth region 541 is made larger than the inclination angle β2 of the sixth region 543 of the second side surface 54 relative to the fourth region 541.

Next, as shown in FIG. 18, a fourth step P4 is performed to cut the first support portion 22 and the second support portion 23. In the fourth step P4, the second surface 22B of the first support portion 22 and the fourth surface 23B of the second support portion 23 are supported by a supporting member 81. Then, a loading body 82 is used to apply a compressive force P to the top surface 51 of the sealing resin 50, thereby cutting the first support portion 22 and the second support portion 23. In the fourth step P4, a first end surface 22C, which corresponds to the cut surface of the first support portion 22, is formed at the first end portion 223. In addition, a second end surface 23C, which corresponds to the cut surface of the second support portion 23, is formed at the second end portion 233. The first support portion 22 is cut starting from the first recess 224. The second support portion 23 is cut starting from the second recess 234. The semiconductor device A10 is obtained through the above steps.

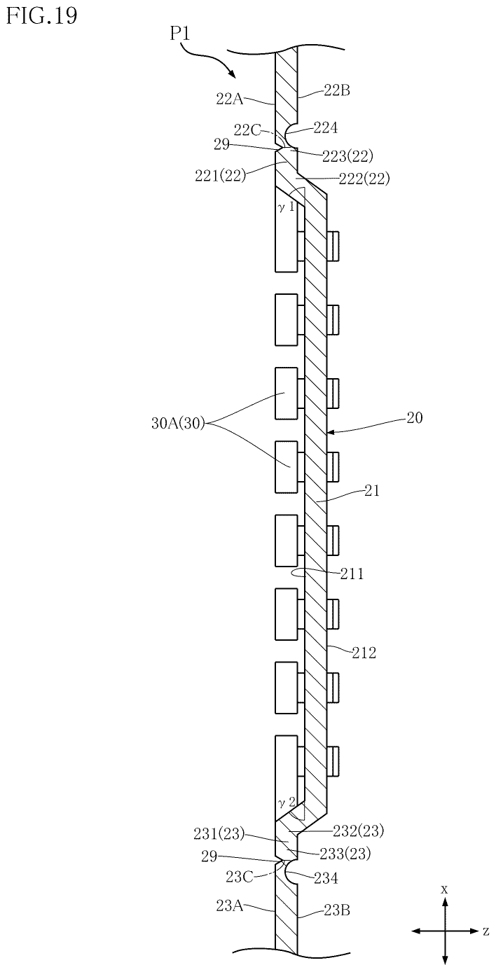

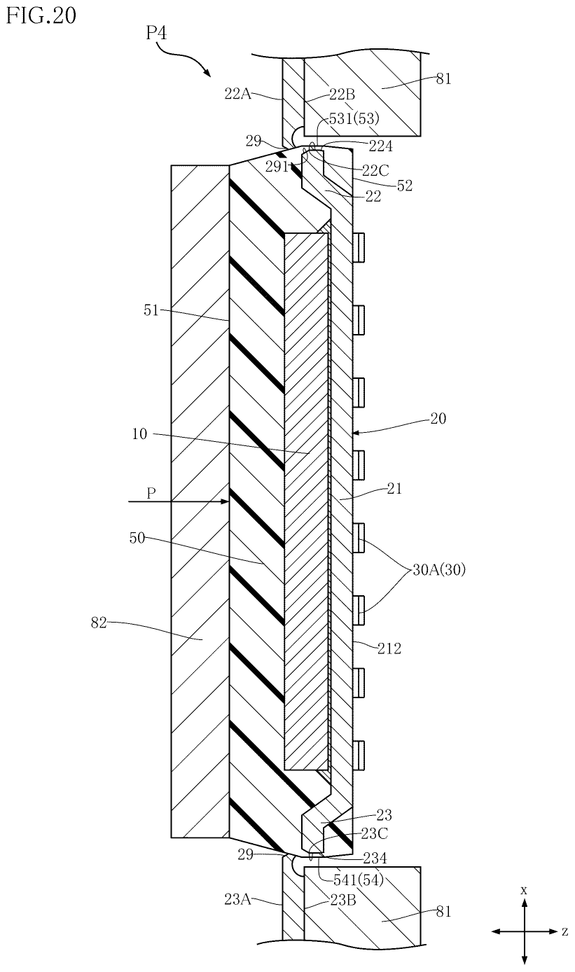

Next, an example of a method for manufacturing the semiconductor device A11 will be described with reference to FIGS. 19 and 20. FIGS. 19 and 20 correspond to FIG. 9 which shows the semiconductor device A10.

As shown in FIG. 19, in a first step P1 for manufacturing the semiconductor device A11, a groove 29 recessed from the first surface 22A of the first support portion 22 and a groove 29 recessed from the third surface 23A of the second support portion 23 are formed in the first support portion 22 and the second support portion 23, respectively. As viewed in the first direction z, the groove 29 formed in the first support portion 22 overlaps with the first recess 224. As viewed in the first direction z, the groove 29 formed in the second support portion 23 overlaps with the second recess 234. The second step P2 and the third step P3 for manufacturing the semiconductor device A11 are the same as those for manufacturing the semiconductor device A10. Thus, descriptions thereof are omitted.

As shown in FIG. 20, in a fourth step P4 for manufacturing the semiconductor device A11, the first support portion 22 is cut starting from both of the first recess 224 and the groove 29. The second support portion 23 is cut starting from both of the second recess 234 and the groove 29. In the first support portion 22, a part of an inner peripheral surface 291 defining the groove 29 corresponds to the first intermediate surface 223A of the first end portion 223.

The following describes advantages of the method for manufacturing the semiconductor device A10.

The method for manufacturing the semiconductor device A10 includes the first step P1 for forming the first lead 20 having the pad portion 21 and the first support portion 22, the second step P2 for bonding the semiconductor element 10 to the pad portion 21, the third step P3 for forming the sealing resin 50, and the fourth step P4 for cutting the first support portion 22. In the third step P3, the pad portion 21 is exposed from the bottom surface 52 of the sealing resin 50. In the third step P3, the dimension H2 of the sealing resin 50 in the first direction z extending from the bottom surface 52 to the second surface 22B of the first support portion 22 is made smaller than the dimension H1 of the sealing resin 50 in the first direction z extending from the top surface 51 of the sealing resin 50 to the first surface 22A of the first support portion 22. In the fourth step P4, the first support portion 22 is cut by applying the compressive force P to the top surface 51 while the second surface 22B is supported by the supporting member 81. In the fourth step P4, the first end surface 22C, which faces one side in the second direction x and is exposed from the sealing resin 50, is formed in the first support portion 22. With this configuration, in the fourth step P4 shown in FIG. 18, the concentration of compressive stress acting on the sealing resin 50 from the first support portion 22 caused by the cutting of the first support portion 22 is reduced. Thus, with this configuration, it is possible to reduce stress concentration in the sealing resin 50 caused by the cutting of the first lead 20 during the manufacturing of the semiconductor device A10.

In the first step P1, the cross-sectional area of the first end portion 223 of the first support portion 22 taken along a direction perpendicular to the second direction x is decreased from the first main portion 221 to the first end surface 22C. This configuration allows a reduction in the area of the first end surface 22C, thereby facilitating the cutting of the first support portion 22 in the fourth step P4 shown in FIG. 18.

In the first step P1 for manufacturing the semiconductor device A10, the first recess 224 recessed from the second surface 22B is formed in the first support portion 22 that includes the first end portion 223. The first recess 224 is connected to the first main portion 221 With this configuration, in the fourth step P4 shown in FIG. 18, the first support portion 22 is cut starting from the first recess 224 with the compressive force P acting on the top surface 51 of the sealing resin 50, thereby facilitating the cutting of the first support portion 22 in the fourth step P4 shown in FIG. 18. Furthermore, the dimension h of the first end surface 22C of the first support portion 22 in the first direction z can be further reduced as compared to the dimension b of the first end surface 22C in the third direction y. This further reduces the second moment of area of the first end surface 22C about the third direction y.

In the first step P1, the first connecting portion 222 of the first support portion 22 is inclined relative to the mounting surface 211 toward a side away from the pad portion 21 in the second direction x. With this configuration, in the fourth step P4 shown in FIG. 18, the concentration of compressive stress acting on the sealing resin 50 from the first support portion 22 caused by the cutting of the first support portion 22 is further reduced. This further reduces stress concentration in the sealing resin 50 caused by the cutting of the first lead 20.

In the third step P3, the inclination angle α1 of the second region 532 of the first side surface 53 relative to the first region 531 of the first side surface 53 is made larger than the inclination angle β1 of the third region 533 of the first side surface 53 relative to the first region 531. With this configuration, even when the dimension H1 shown in FIG. 9 is larger than the dimension H2 in the third step P3 shown in FIG. 19, defects in the sealing resin 50 caused by the withdrawal of a molding die can be reduced.

### Second Embodiment

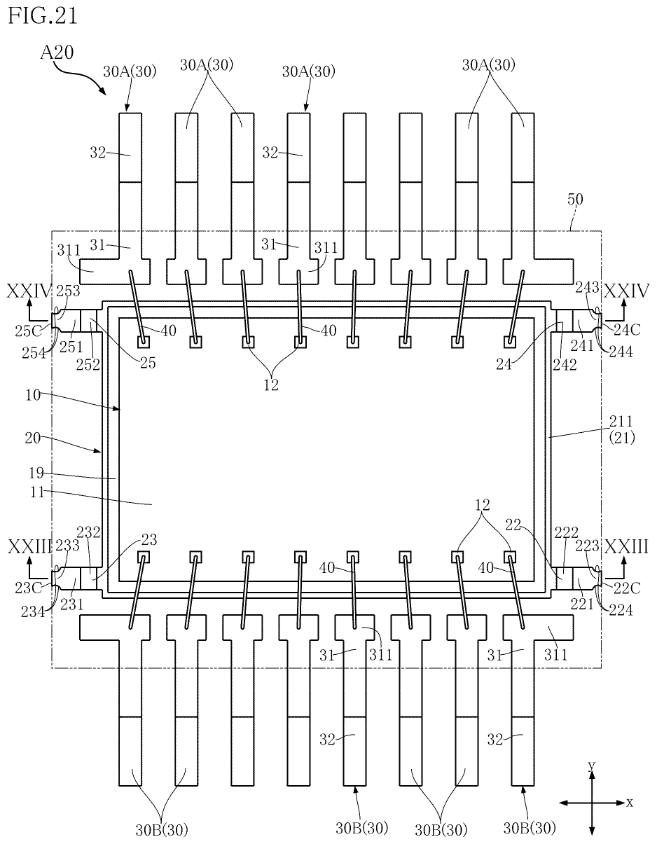

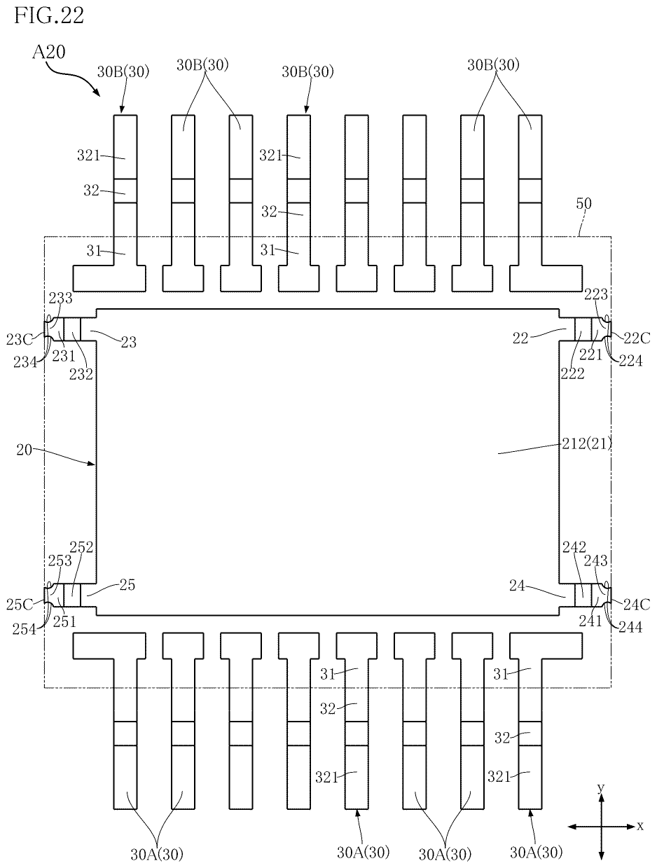

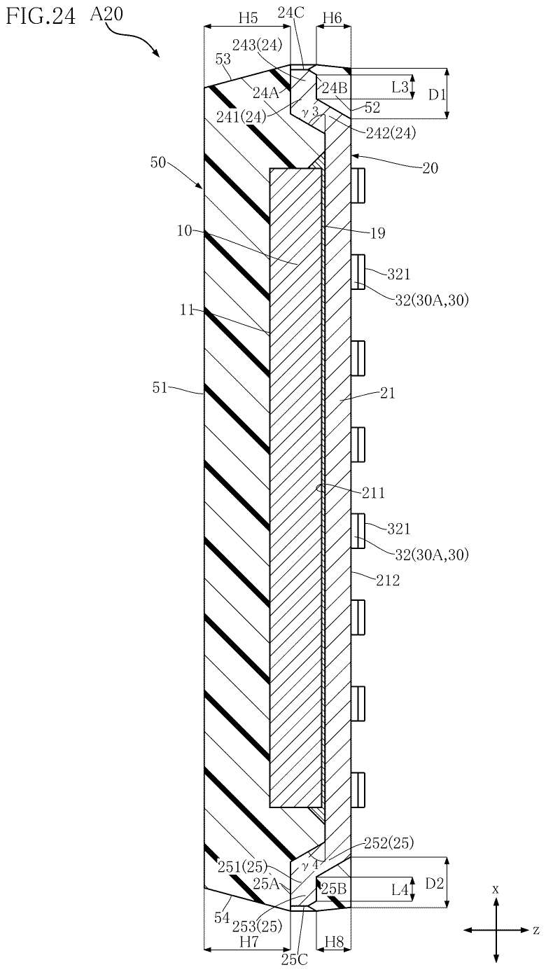

The following describes a semiconductor device A20 according to a second embodiment of the present disclosure, with reference to FIGS. 21 to 26. In these figures, elements that are the same as or similar to the elements in the semiconductor device A10 are provided with the same reference numerals, and descriptions thereof are omitted. In FIGS. 21 and 22, the sealing resin 50 is shown in phantom for convenience of understanding. In FIGS. 21 and 22, the outline of the sealing resin 50 is indicated by imaginary lines.

The semiconductor device A20 is different from the semiconductor device A10 in the configurations of the first support portion 22, the second support portion 23, the third support portion 24, and the fourth support portion 25 of the first lead 20.

As shown in FIGS. 21 and 22, the first end portion 223 is provided with two first recesses 224 recessed from the respective sides in the third direction y. Each of the two first recesses 224 is connected to the periphery of the first surface 22A of the first end portion 223 and the periphery of the second surface 22B of the first end portion 223. The second end portion 233 is provided with two second recesses 234 recessed from the respective sides in the third direction y. Each of the two second recesses 234 is connected to the periphery of the third surface 23A of the second end portion 233 and the fourth surface 23B of the second end portion 233.

As shown in FIGS. 21 and 22, the third end portion 243 is provided with two third recess 244 recessed from the respective sides in the third direction y. Each of the two third recesses 244 is connected to the periphery of the fifth surface 24A of the third end portion 243 and the periphery of the sixth surface 24B of the third end portion 243. The fourth end portion 253 is provided with two fourth recesses 254 recessed from the respective sides in the third direction y. Each of the two fourth recesses 254 is connected to the periphery of the seventh surface 25A of the fourth end portion 253 and the periphery of the eighth surface 25B.

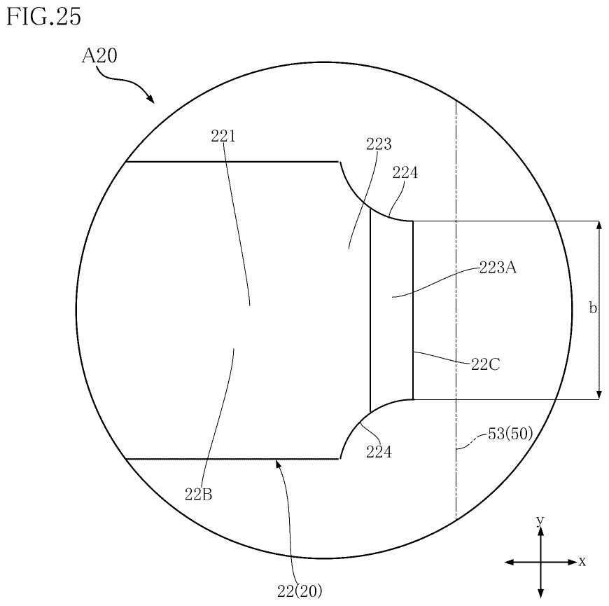

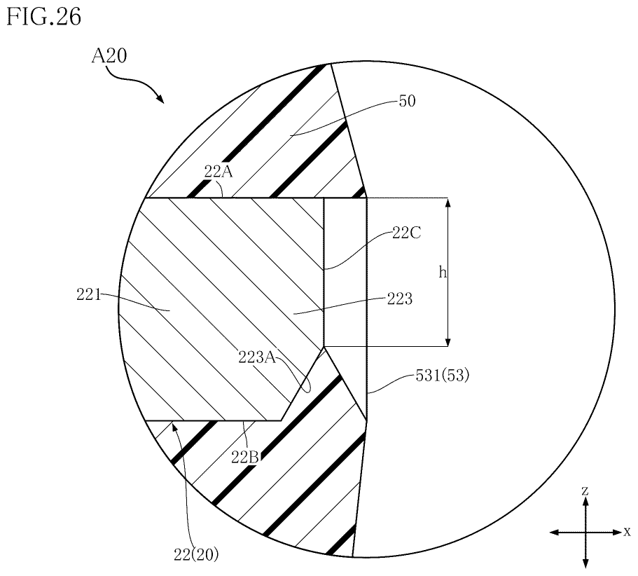

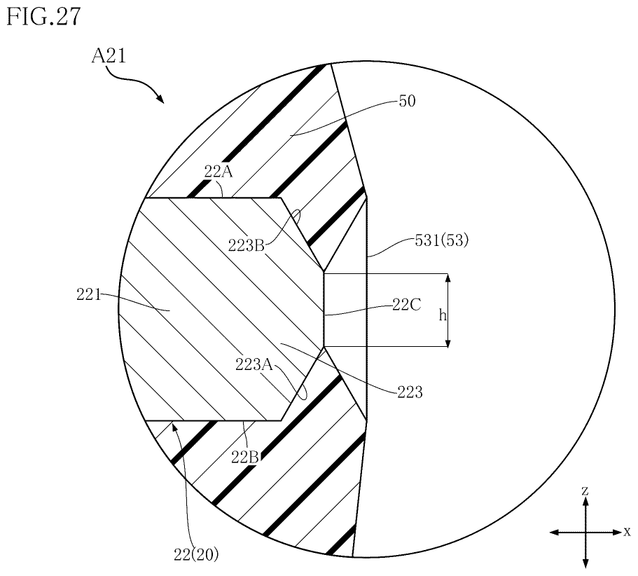

As shown in FIGS. 25 and 26, the first end portion 223 has a first intermediate surface 223A, which is located between the second surface 22B and the first end surface 22C in the second direction x and connected to the second surface 22B. As viewed in the second direction x, the first intermediate surface 223A overlaps with the first main portion 221. The first end surface 22C is located between the first intermediate surface 223A and the first surface 22A in the first direction z. The dimension of the first intermediate surface 223A in the second direction x is smaller than the dimension L1 of the second surface 22B of the first end portion 223. The first intermediate surface 223A is inclined relative to the second surface 22B toward the inside of the first end portion 223 in the first direction z, and is connected to the first end surface 22C. The first intermediate surface 223A is covered with the sealing resin 50. The first end surface 22C is spaced apart from the first region 531 of the first side surface 53 of the sealing resin 50 toward the side in the second direction x where the pad portion 21 is located.

Next, a semiconductor device A21 according to a variation of the second embodiment of the present disclosure will be described with reference to FIG. 27. FIG. 27 corresponds to FIG. 26 that shows the semiconductor device A20. The semiconductor device A21 is different from the semiconductor device A20 in the configuration of the first support portion 22 of the first lead 20.

As shown in FIG. 27, the first end portion 223 has a second intermediate surface 223B, which is located between the first surface 22A and the first end surface 22C in the second direction x and connected to the first surface 22A. As viewed in the second direction x, the second intermediate surface 223B overlaps with the first main portion 221. The first end surface 22C is located between the first intermediate surface 223A and the second intermediate surface 223B in the first direction z. The dimension of the second intermediate surface 223B in the second direction x is smaller than the dimension of the first surface 22A of the first end portion 223 in the second direction x. The second intermediate surface 223B is inclined relative to the first surface 22A toward the inside of the first end portion 223 in the first direction z, and is connected to the first end surface 22C. The second intermediate surface 223B is covered with the sealing resin 50.

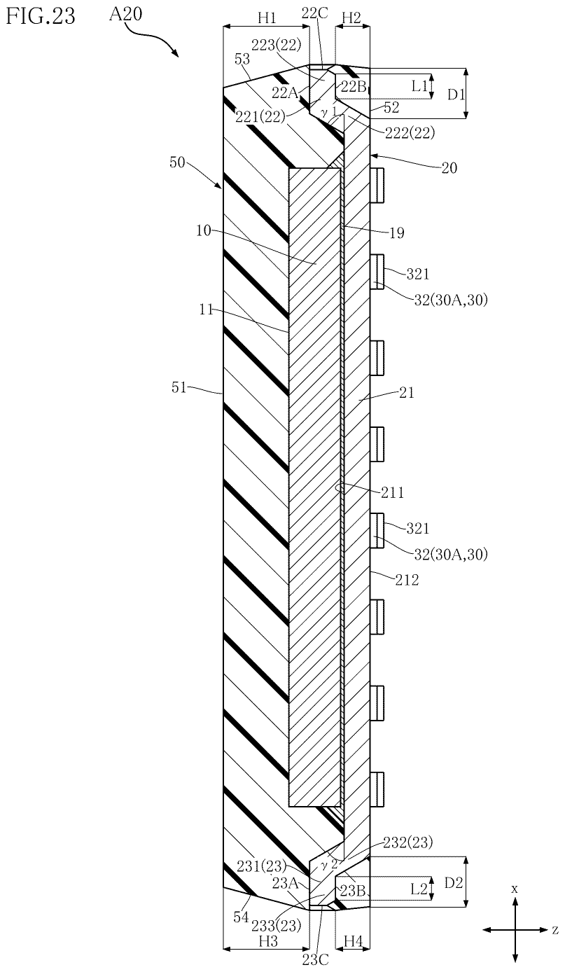

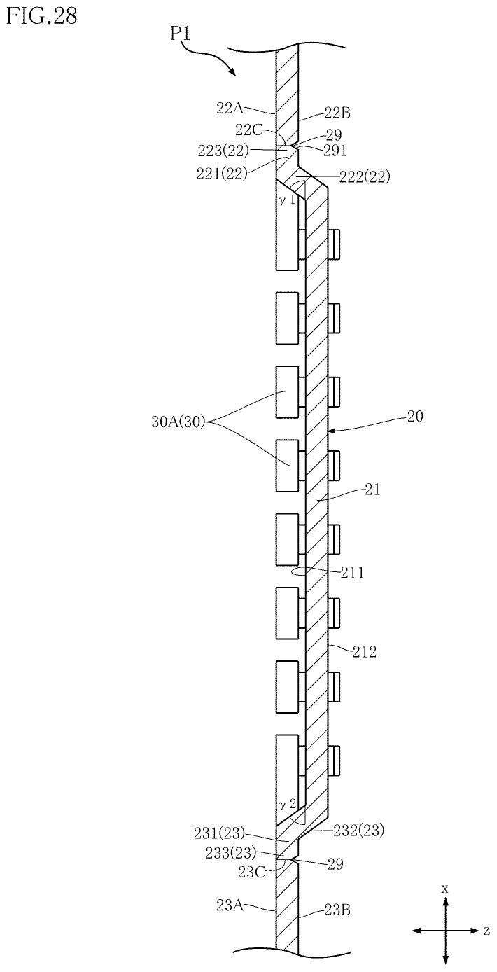

Next, an example of a method for manufacturing the semiconductor device A20 will be described with reference to FIGS. 28 to 30. FIGS. 28 to 30 correspond to FIG. 23 which shows the semiconductor device A20.

First, as shown in FIG. 28, a first step P1 is performed to form a first lead 20 having a pad portion 21, a first support portion 22, and a second support portion 23. In the first step P1, two first recesses 224 are formed in the first end portion 223 of the first support portion 22, so that the cross-sectional area of the first end portion 223 taken along a direction perpendicular to the second direction x decreases from the first main portion 221 of the first support portion 22 to the first end surface 22C. In addition, two second recesses 234 are formed in the second end portion 233 of the second support portion 23, so that the cross-sectional area of the second end portion 233 taken along a direction perpendicular to the second direction x decreases from the second main portion 231 of the second support portion 23 to the second end surface 23C.

As shown in FIG. 28, in the first step P1, a groove 29 recessed from the second surface of the first support portion 22 and a groove 29 recessed from the fourth surface 23B of the second support portion 23 are formed in the first support portion 22 and the second support portion 23, respectively. The grooves 29 extend in the third direction y. Each of the grooves 29 is defined by an inner peripheral surface 291 connected to either the second surface 22B or the fourth surface 23B. The groove 29 formed in the first support portion 22 is located opposite the first main portion 221 with respect to the two first recesses 224 in the second direction x. The groove 29 formed in the second support portion 23 is located opposite the second main portion 231 with respect to the two second recesses 234 in the second direction x.

Next, a second step P2 is performed to bond a semiconductor element 10 to the mounting surface 211 of the pad portion 21. The second step P2 is the same as the second step P2 for manufacturing the semiconductor device A10 shown in FIG. 16. Thus, a description thereof is omitted.

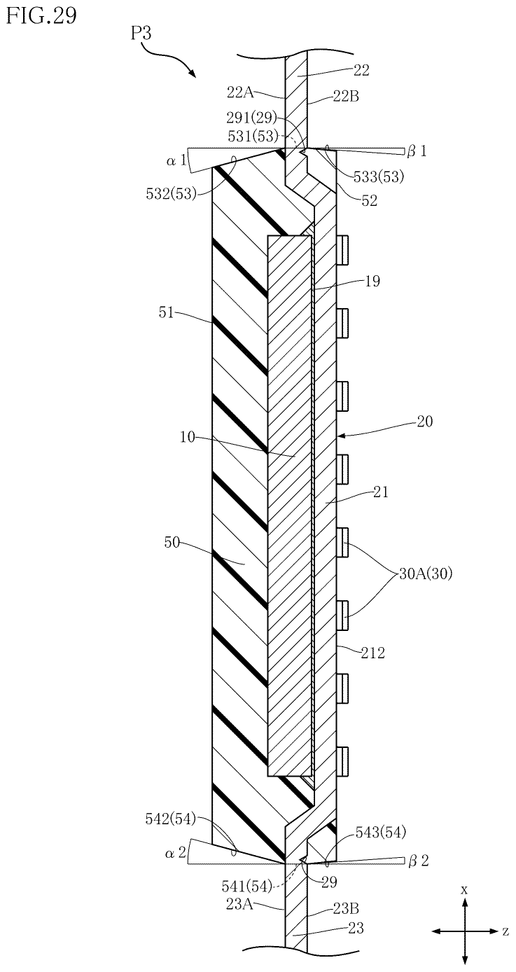

Next, as shown in FIG. 29, a third step P3 is performed to form a sealing resin 50 that covers a part of each of the pad portion 21, the first support portion 22, and the second support portion 23, and the semiconductor element 10. In the third step P3, the grooves 29 formed in the first support portion 22 and the second support portion 23 are covered with the sealing resin.

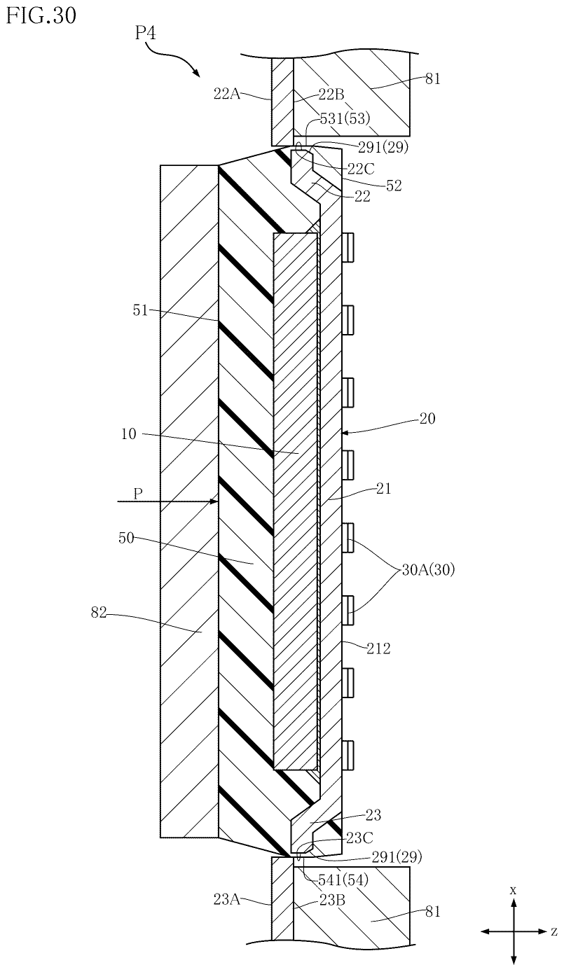

Next, as shown in FIG. 30, a fourth step P4 is performed to cut the first support portion 22 the second support portion 23. Each of the first support portion 22 and the second support portion 23 is cut starting from the corresponding groove 29. In the first support portion 22, a part of an inner peripheral surface 291 defining the groove 29 corresponds to the first intermediate surface 223A of the first end portion 223. The semiconductor device A20 is obtained through the above steps.

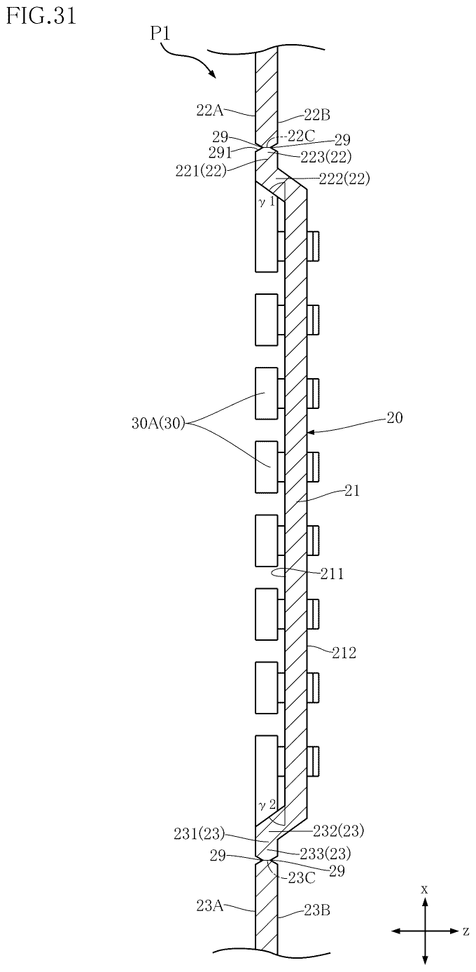

Next, an example of a method for manufacturing the semiconductor device A21 will be described with reference to FIG. 31. FIG. 31 corresponds to FIG. 23 that shows the semiconductor device A20.

As shown in FIG. 31, in a first step P1 for manufacturing the semiconductor device A21, grooves 29 that are each recessed from one of the first surface 22A and the second surface 22B of the first support portion 22 are formed in the first support portion 22, and grooves 29 that are each recessed from one of the third surface 23A and the fourth surface 23B of the second support portion 23 are formed in the second support portion 23. As viewed in the first direction z, the groove 29 formed in the second surface 22B of the first support portion 22 overlaps with the groove 29 formed in the first surface 22A of the first support portion 22. Furthermore, as viewed in the first direction z, the groove 29 formed in the fourth surface 23B of the second support portion 23 overlaps with the groove 29 formed in the third surface 23A of the second support portion 23. The second step P2, the third step P3, and the fourth step P4 for manufacturing the semiconductor device A21 are the same as those for manufacturing the semiconductor device A20. Thus, descriptions thereof are omitted.

The following describes advantages of the method for manufacturing the semiconductor device A20.

The method for manufacturing the semiconductor device A20 includes the first step P1 for forming the first lead 20 having the pad portion 21 and the first support portion 22, the second step P2 for bonding the semiconductor element 10 to the pad portion 21, the third step P3 for forming the sealing resin 50, and the fourth step P4 for cutting the first support portion 22. In the third step P3, the pad portion 21 is exposed from the bottom surface 52 of the sealing resin 50. In the third step P3, the dimension H2 of the sealing resin 50 in the first direction z extending from the bottom surface 52 to the second surface 22B of the first support portion 22 is made smaller than the dimension H1 of the sealing resin 50 in the first direction z extending from the top surface 51 of the sealing resin 50 to the first surface 22A of the first support portion 22. In the fourth step P4, the first support portion 22 is cut by applying the compressive force P to the top surface 51 while the second surface 22B is supported by the supporting member 81. In the fourth step P4, the first end surface 22C, which faces one side in the second direction x and is exposed from the sealing resin 50, is formed in the first support portion 22. Thus, with this configuration, it is possible to reduce stress concentration in the sealing resin 50 caused by the cutting of the first lead 20 during the manufacturing of the semiconductor device A20. Furthermore, the manufacturing method of the semiconductor device A20 has features common to the manufacturing method for the semiconductor device A10, thereby achieving the same advantages as the manufacturing method of the semiconductor device A10.

The first end portion 223 of the first support portion 22 has the first intermediate surface 223A. As viewed in the second direction x, the first intermediate surface 223A overlaps with the first main portion 221. The first end surface 22C of the first support portion 22 is located between the first intermediate surface 223A and the first surface 22A in the first direction z. The first intermediate surface 223A corresponds to a part of the inner peripheral surface 291 defining the groove 29 formed in the first step P1. With this configuration, the dimension h of the first end surface 22C of the first support portion 22 in the first direction z can be further reduced as compared to the dimension b of the first end surface 22C in the third direction y. This further reduces the second moment of area of the first end surface 22C about the y-axis in the third direction y, thereby facilitating the cutting of the first support portion 22 in the fourth step P4 shown in FIG. 30.

The present disclosure is not limited to the above embodiments. Various design changes can be made to the specific configurations of the elements in the present disclosure. The present disclosure includes the embodiments described in the following clauses.

### Clause 1.

A method for manufacturing a semiconductor device, comprising:
a first step of forming a first lead that includes a pad portion and a first support portion, the pad portion including a mounting surface facing one side in a first direction, the first support portion being connected to the pad portion on one side in a second direction perpendicular to the first direction;
a second step of bonding a semiconductor element to the mounting surface;
a third step of forming a sealing resin that covers the semiconductor element and a part of each of the pad portion and the first support portion; and
a fourth step of cutting the first support portion,
wherein the sealing resin includes a top surface facing a same side as the mounting surface in the first direction, and a bottom surface facing away from the top surface in the first direction,
the first support portion includes a first surface facing a same side as the mounting surface in the first direction, and a second surface facing away from the first surface in the first direction,
in the third step, the sealing resin is formed such that a part of each of the first surface and the second surface is covered with the sealing resin and the pad portion is exposed from the bottom surface, and that a dimension of the sealing resin in the first direction extending from the bottom surface to the second surface is smaller than a dimension of the sealing resin in the first direction extending from the top surface to the first surface,
in the fourth step, the first support portion is cut by applying a compressive force to the top surface while the second surface is supported by a supporting member, and
in the fourth step, a first end surface, which faces one side in the second direction is exposed from the sealing resin, is formed in the first support portion.

### Clause 2.

The method according to clause 1, wherein in the third step, the sealing resin is formed such that the dimension of the sealing resin in the first direction extending from the bottom surface to the second surface is no greater than 50% of the dimension of the sealing resin in the first direction extending from the top surface to the first surface.

### Clause 3.

The method according to clause 1, wherein the first support portion includes a first main portion including the first surface and the second surface that are covered with the sealing resin, a first connecting portion connected to the first main portion and the pad portion, and a first end portion located opposite the first connecting portion with respect to the first main portion in the second direction and connected to the first main portion,
the first end portion includes the first surface covered with the sealing resin and the first end surface formed in the fourth step, and
in the first step, a cross-sectional area of the first end portion taken along a direction perpendicular to the second direction is decreased from the first main portion to a position at which the first end surface is formed in the fourth step.

### Clause 4.

The method according to clause 3, in the fourth step, the first end surface is formed suc that a dimension of the first end surface in a third direction perpendicular to the first direction and the second direction is different from a dimension of the first end surface in the first direction.

### Clause 5.

The method according to clause 4, wherein in the fourth step, the first end surface is formed such that the dimension of the first end surface in the first direction is smaller than the dimension of the first end surface in the third direction.

### Clause 6.

The method according to clause 5, wherein in the first step, a recess that is recessed from the second surface is formed in the first support portion including the first end portion, and
the recess is connected to the first main portion.

### Clause 7.

The method according to clause 6, wherein in the first step, a groove, which is recessed from the first surface and extends in the third direction, is formed in the first support portion,
as viewed in the first direction, the groove overlaps with the recess, and
in the fourth step, the first support portion is cut starting from the groove.

### Clause 8.

The method according to clause 7, wherein the first support portion includes an inner peripheral surface defining the groove, and
in the fourth step, the first end surface is connected to the periphery of the inner peripheral surface.

### Clause 9.

The method according to clause 4, wherein in the first step, a recess that is recessed from one side in the third direction is formed in the first support portion including the first end portion, and
the recess is connected to a periphery of the first surface.

### Clause 10.

The method according to clause 9, wherein in the first step, a groove, which is recessed from the first surface and extends in the third direction, is formed in the first support portion,
the groove is located opposite the first main portion with respect to the recess in the second direction, and
in the fourth step, the first support portion is cut starting from the groove.

### Clause 11.

The method according to any of clauses 4 to 10, wherein in the first step, the first connecting portion is inclined relative to the mounting surface toward a side away from the pad portion in the second direction.

### Clause 12.

The method according to clause 11, wherein an inclination angle of the first connecting portion relative to the mounting surface is no greater than 50°.

### Clause 13.

The method according to clause 11, wherein the first lead includes a second support portion that is located opposite the first support portion with respect to the pad portion in the second direction, and that is connected to the pad portion,
the second support portion includes a third surface facing the same side as the mounting surface in the first direction, and a fourth surface facing away from the third surface in the first direction,
in the third step, the sealing resin is formed such that a part of each of the third surface and fourth surface is covered with the sealing resin, and that a dimension of the sealing resin in the first direction extending from the bottom surface to the fourth surface is smaller than a dimension of the sealing resin in the first direction extending from the top surface to the third surface,
in the fourth step, the second support portion is cut by applying a load to the top surface while the fourth surface is supported by the supporting member, and
in the fourth step, a second end surface, which faces away from the first end surface the second direction and is exposed from the sealing resin, is formed in the second support portion.

### Clause 14.

The method according to clause 13, wherein the sealing resin includes a first side surface facing the same side as the first end surface in the second direction,
the first side surface includes a first region including the first direction as an in-plane direction, a second region located between the first region and the top surface in the first direction, and a third region located opposite the second region with respect to the first region,
in the third step, the second region and the third region are inclined relative to the region, and
in the fourth step, the first end surface is exposed from the first region.

### Clause 15.

The method according to clause 14, wherein in the third step, the sealing resin is formed such that an inclination angle of the second region relative to the first region is made larger than an inclination angle of the third region relative to the first region.

### Clause 16.

A semiconductor device comprising:
a first lead including a pad portion and a first support portion, the pad portion including a mounting surface facing one side in a first direction, the first support portion being connected to the pad portion on one side in a second direction perpendicular to the first direction;
a semiconductor element bonded to the mounting surface; and
a sealing resin covering the semiconductor element and a part of the first lead,
wherein the sealing resin includes a top surface facing a same side as the mounting surface in the first direction, and a bottom surface facing away from the top surface in the first direction, the pad portion being exposed from the bottom surface,
the first support portion includes a first surface facing a same side as the top surface in first direction and covered with the sealing resin, a second surface facing away from the first surface in the first direction and covered with the sealing resin, and a first end surface facing in the second direction and exposed from the sealing resin,
a dimension of the sealing resin in the first direction extending from the bottom surface to the second surface is smaller than a dimension of the sealing resin in the first direction extending from the top surface to the first surface, and
a cross-sectional area of the first support portion taken along a direction perpendicular to the second direction decreases from a side at which the pad portion is located to the first end surface.

### Clause 17.

The semiconductor device according to clause 16, wherein a dimension of the first end surface in the first direction is smaller than a dimension of the first end surface in a third direction perpendicular to the first direction and the second direction,
the first support portion is formed with a recess recessed from the second surface, an

the recess is located between the second surface and the first end surface in the second direction.

### REFERENCE NUMERALS

A10, A 20: Semiconductor device 10: Semiconductor element
11: Element surface 12: Electrode
19: Bonding layer 20: First lead
21: Pad portion 211: Mounting surface
212: Exposed surface 22: First support portion
22A: First surface 22B: Second surface
22C: First end surface 221: First main portion
222: First connecting portion 223: First end portion
223A: First intermediate surface 223B: Second intermediate surface
224: First recess 23: Second support portion
23A: Third surface 23B: Fourth surface
23C: Second end surface 231: Second main portion
232: Second connecting portion 233: Second end portion
234: Second recess 24: Third support portion
24A: Fifth surface 24B: Sixth surface
24C: Third end surface 241: Third main portion
242: Third connecting portion 243: Third end portion
244: Third recess 25: Fourth support portion
25A: Seventh surface 25B: Eighth surface
25C: Fourth end surface 251: Fourth main portion
252: Fourth connecting portion 253: Fourth end portion
254: Fourth recess 29: Groove
291: Inner peripheral surface 30: Second lead
30A: First terminal 30B: Second terminal
31: Inner portion 311: Connecting surface
32: Outer portion 321: Mounting surface
40: Wire 50: Sealing resin
51: Top surface 52: Bottom surface
53: First side surface 531 to 533: First to third regions
54: Second side surface 541 to 543: Fourth to sixth regions
55: Third side surface 551 to 553: Seventh to ninth regions
P1 to P4: First to fourth steps z: First direction
x: Second direction y: Third direction

1. A method for manufacturing a semiconductor device, comprising:
a first step of forming a first lead that includes a pad portion and a first support portion, the pad portion including a mounting surface facing one side in a first direction, the first support portion being connected to the pad portion on one side in a second direction perpendicular to the first direction;
a second step of bonding a semiconductor element to the mounting surface;
a third step of forming a sealing resin that covers the semiconductor element and a part of each of the pad portion and the first support portion; and
a fourth step of cutting the first support portion,
wherein the sealing resin includes a top surface facing a same side as the mounting surface in the first direction, and a bottom surface facing away from the top surface in the first direction,
the first support portion includes a first surface facing a same side as the mounting surface in the first direction, and a second surface facing away from the first surface in the first direction,
in the third step, the sealing resin is formed such that a part of each of the first surface and the second surface is covered with the sealing resin and the pad portion is exposed from the bottom surface, and that a dimension of the sealing resin in the first direction extending from the bottom surface to the second surface is smaller than a dimension of the sealing resin in the first direction extending from the top surface to the first surface,
in the fourth step, the first support portion is cut by applying a compressive force to the top surface while the second surface is supported by a supporting member, and
in the fourth step, a first end surface, which faces one side in the second direction and is exposed from the sealing resin, is formed in the first support portion.

2. The method according to claim 1, wherein in the third step, the sealing resin is formed such that the dimension of the sealing resin in the first direction extending from the bottom surface to the second surface is no greater than 50% of the dimension of the sealing resin in the first direction extending from the top surface to the first surface.

3. The method according to claim 1, wherein the first support portion includes a first main portion including the first surface and the second surface that are covered with the sealing resin, a first connecting portion connected to the first main portion and the pad portion, and a first end portion located opposite the first connecting portion with respect to the first main portion in the second direction and connected to the first main portion,
the first end portion includes the first surface covered with the sealing resin and the first end surface formed in the fourth step, and
in the first step, a cross-sectional area of the first end portion taken along a direction perpendicular to the second direction is decreased from the first main portion to a position at which the first end surface is formed in the fourth step.

4. The method according to claim 3, wherein in the fourth step, the first end surface is formed such that a dimension of the first end surface in a third direction perpendicular to the first direction and the second direction is different from a dimension of the first end surface in the first direction.

5. The method according to claim 4, wherein in the fourth step, the first end surface is formed such that the dimension of the first end surface in the first direction is smaller than the dimension of the first end surface in the third direction.

6. The method according to claim 5, wherein in the first step, a recess that is recessed from the second surface is formed in the first support portion including the first end portion, and
the recess is connected to the first main portion.

7. The method according to claim 6, wherein in the first step, a groove, which is recessed from the first surface and extends in the third direction, is formed in the first support portion,
as viewed in the first direction, the groove overlaps with the recess, and
in the fourth step, the first support portion is cut starting from the groove.

8. The method according to claim 7, wherein the first support portion includes an inner peripheral surface defining the groove, and
in the fourth step, the first end surface is connected to the periphery of the inner peripheral surface.

9. The method according to claim 4, wherein in the first step, a recess that is recessed from one side in the third direction is formed in the first support portion including the first end portion, and
the recess is connected to a periphery of the first surface.

10. The method according to claim 9, wherein in the first step, a groove, which is recessed from the first surface and extends in the third direction, is formed in the first support portion,
the groove is located opposite the first main portion with respect to the recess in the second direction, and
in the fourth step, the first support portion is cut starting from the groove.

11. The method according to claim 4, wherein in the first step, the first connecting portion is inclined relative to the mounting surface toward a side away from the pad portion in the second direction.

12. The method according to claim 11, wherein an inclination angle of the first connecting portion relative to the mounting surface is no greater than 50°.

13. The method according to claim 11, wherein the first lead includes a second support portion that is located opposite the first support portion with respect to the pad portion in the second direction, and that is connected to the pad portion,
the second support portion includes a third surface facing the same side as the mounting surface in the first direction, and a fourth surface facing away from the third surface in the first direction,
in the third step, the sealing resin is formed such that a part of each of the third surface and the fourth surface is covered with the sealing resin, and that a dimension of the sealing resin in the first direction extending from the bottom surface to the fourth surface is smaller than a dimension of the sealing resin in the first direction extending from the top surface to the third surface,
in the fourth step, the second support portion is cut by applying a load to the top surface while the fourth surface is supported by the supporting member, and
in the fourth step, a second end surface, which faces away from the first end surface in the second direction and is exposed from the sealing resin, is formed in the second support portion.

14. The method according to claim 13, wherein the sealing resin includes a first side surface facing the same side as the first end surface in the second direction,
the first side surface includes a first region including the first direction as an in-plane direction, a second region located between the first region and the top surface in the first direction, and a third region located opposite the second region with respect to the first region,
in the third step, the second region and the third region are inclined relative to the first region, and
in the fourth step, the first end surface is exposed from the first region.

15. The method according to claim 14, wherein in the third step, the sealing resin is formed such that an inclination angle of the second region relative to the first region is made larger than an inclination angle of the third region relative to the first region.

16. A semiconductor device comprising:
a first lead including a pad portion and a first support portion, the pad portion including a mounting surface facing one side in a first direction, the first support portion being connected to the pad portion on one side in a second direction perpendicular to the first direction;
a semiconductor element bonded to the mounting surface; and
a sealing resin covering the semiconductor element and a part of the first lead,
wherein the sealing resin includes a top surface facing a same side as the mounting surface in the first direction, and a bottom surface facing away from the top surface in the first direction, the pad portion being exposed from the bottom surface,
the first support portion includes a first surface facing a same side as the top surface in the first direction and covered with the sealing resin, a second surface facing away from the first surface in the first direction and covered with the sealing resin, and a first end surface facing in the second direction and exposed from the sealing resin,
a dimension of the sealing resin in the first direction extending from the bottom surface to the second surface is smaller than a dimension of the sealing resin in the first direction extending from the top surface to the first surface, and
a cross-sectional area of the first support portion taken along a direction perpendicular to the second direction decreases from a side at which the pad portion is located to the first end surface.

17. The semiconductor device according to claim 16, wherein a dimension of the first end surface in the first direction is smaller than a dimension of the first end surface in a third direction perpendicular to the first direction and the second direction,
the first support portion is formed with a recess recessed from the second surface, and
the recess is located between the second surface and the first end surface in the second direction.
